(19) United States
(12) Patent Application Publication
(10) Pub. No.: US 2011/0134598 A1
(43) Pub. Date: Jun. 9, 2011

(54) HARD DISK BRACKET ASSEMBLY

(75) Inventor: SHENG-CHUNG HSIAO, Tu-Cheng (TW)

(73) Assignee: HON HAI PRECISION INDUSTRY CO., LTD., Tu-Cheng (TW)

(21) Appl. No.: 12/758,736

(22) Filed: Apr. 12, 2010

(30) Foreign Application Priority Data
Dec. 3, 2009 (CN) 200910310807.4

(51) Int. Cl. H05K 5/02

(52) U.S. Cl. 361/679.33

(57) ABSTRACT

A hard disk bracket assembly for fixing a hard disk includes a holding portion and a locking portion. The holding portion includes a bottom wall, a first flexible sidewall and a second flexible sidewall. The bottom wall interconnects the first flexible sidewall and the second flexible sidewall. The first flexible sidewall and the second flexible sidewall are substantially perpendicular to the bottom wall. The locking portion cooperatively defines a receiving cavity with the holding portion for receiving the hard disk. The locking portion includes a first edge and a second edge opposite to the first edge. The first edge is hinged to the first flexible sidewall rotatably while the second edge is configured for being engaged with the second flexible sidewall, to lock the hark disk in the receiving cavity.

### BACKGROUND

1. Technical Field

This present disclosure relates to hard disks, and particularly, to a hard disk bracket assembly.

2. Description of Related Art

Nowadays, the reading speed of hard disks has improved, resulting in a faster rotating speed of the magnetic heads positioned on the hard disks. However, the hard disk is directly fixed to a main box of a computer without any shock absorbers, which affects the stability and lowers the performance of the hard disk of the hard disk, especially when the reading speed of the magnetic head on the hard disk has been increased.

Therefore, it is desirable to provide a hard disk bracket assembly, which can overcome or at least ease the above-mentioned limitations.

### BRIEF DESCRIPTION OF THE DRAWINGS

FIG. 1 is an isometric, exploded view of a hard disk bracket assembly receiving a hard disk, according to an exemplary embodiment.

FIG. 2 is an assembled view of the hard disk bracket assembly with the hard disk of FIG. 1.

FIG. 3 is a graph showing vibration test result of the hard disk fixed by the hard disk bracket assembly of FIG. 1.

FIG. 4 is similar to FIG. 3, but showing the vibration test result of the hard disk not fixed by the hard disk bracket assembly of FIG. 1.

FIG. 5 is a data sheet showing the test result of the hard disk fixed by the hard disk bracket assembly of FIG. 1.

### DETAILED DESCRIPTION

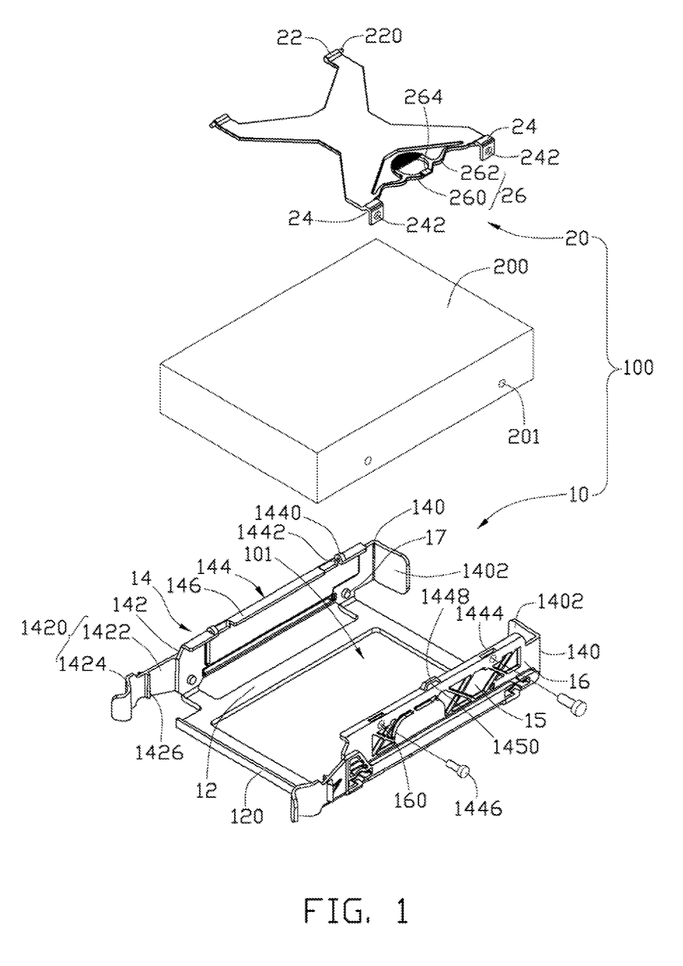

Referring to FIG. 1, a hard disk bracket assembly 100 for fixing a hard disk 200 to a main box of a computer (not shown) is shown. The hard disk 200 defines two inserting holes 201 on each of two opposite sidewalls thereof.

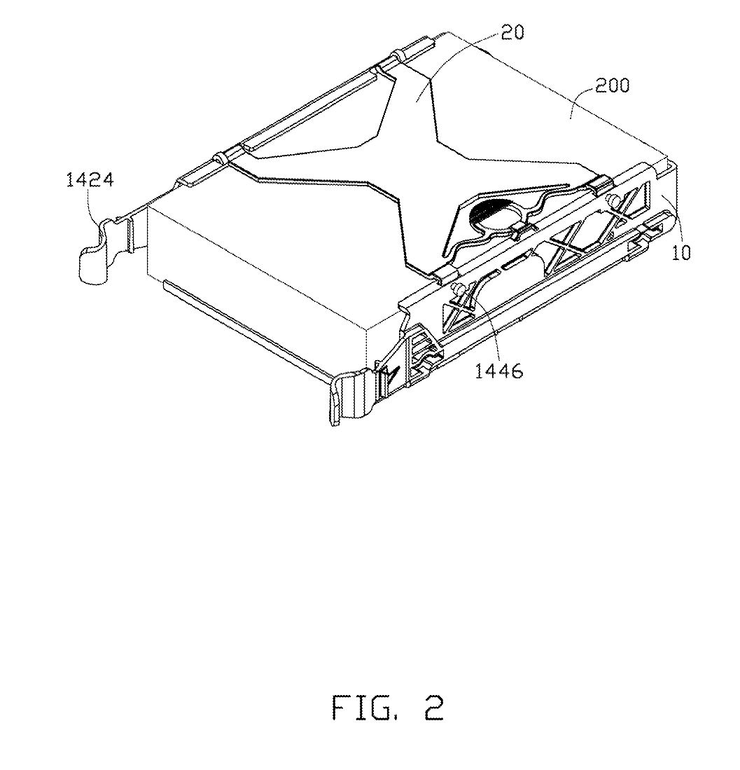

Referring to FIG. 2, the hard disk bracket assembly 100 includes a holding portion 10 and a locking portion 20 rotatably hinged to the holding portion 10. A receiving cavity 101 is cooperatively defined between the holding portion 10 and the locking portion 20, to receive the hard disk 200 therein. In the present disclosure, the hard disk bracket assembly 100 is made of elastic material. In detail, the elastic material may be polymethyl methacrylate (PMMA) or polycarbonate (PC).

The holding portion 10 includes a bottom wall 12, a first flexible sidewall 14, and a second flexible sidewall 16 opposite to the first flexible sidewall 14.

The bottom wall 12 includes a limiting portion 120 extending upwards from a side between the first and second flexible sidewalls 14 and 16, for limiting a horizontal movement of the hard disk 200 on the bottom wall 12. The limiting portion 120 is lower than the first and second flexible sidewalls 14 and 16.

The first flexible sidewall 14 and the second flexible sidewall 16 substantially extend upward perpendicular to the bottom wall 12. In the present disclosure, the first flexible sidewall 14 and the second flexible sidewall 16 are curvedly connected to the bottom wall 12, as such, the first flexible sidewall 14 and the second flexible sidewall 16 can be easily deformed by external force.

The first flexible sidewall 14 and the second flexible sidewall 16 each include a first border 140 away from the limiting portion 120, a second border 142 adjacent to the limiting portion 120, and a third border 144 interconnecting the first border 140 and the second border 142. The extending directions of the first border 140 and the second border 142 are substantially perpendicular to the bottom wall 12 while that of the third border 144 is parallel to the bottom wall 12.

The first borders 140 of the first and second flexible sidewalls 14 and 16 have two resisting portions 1402 protruding and running parallel to the limiting portion 120. The resisting portions 1402 extend towards each other. Each resisting portion 1402 is perpendicular to the bottom wall 12 and the first flexible sidewall 14. The two resisting portions 1402 resist with the main box of the computer, for protecting the hard disk 200 from abrasion by the main box.

Two flexible arms 1420 are fixed to the outer surfaces of the first and second flexible sidewalls 14 and 16, and extend along a direction away from the second border 142. The flexible arms 1420 are configured for assisting in pushing the hard disk 200 to the receiving cavity 101. In detail, each flexible arm 1420 includes a bending portion 1422 and an operating portion 1424 integrally extending from an end of the bending portion 1422. The operating portion 1424 is “S” shaped. When a user presses the operating portion 1424, the bending portion 1422 flexibly deforms to resist the hard disk 200. A first protrusion 1426 is formed between the bending portion 1422 and the operating portion 1424. The first protrusion 1426 extends towards the hard disk 200 and is configured for applying pressure to the hard disk 200 when the hard disk 200 is received in the hard disk bracket assembly 100.

The third border 144 of the first flexible sidewall 14 has two second protrusions 1440 protruding therefrom, each defining a pivoting hole 1442.

The third border 144 of the second flexible sidewall 16 defines two latching grooves 1444 extending to the bottom 12 therefrom. The second flexible sidewall 16 further defines two first screw holes 160 perpendicularly communicating with the latching groove 1444. A screw 1446 can be inserted into the latching groove 1444 through each first screw hole 160. The length of the screw 1446 along the axis thereof is larger than that of the first screw hole 160, thereby the user can adjust the depth of the screw 1446 in the first screw hole 160 to adjust the tightness of the hard disk bracket assembly 100. Furthermore, an arc-shaped element 1448 is disposed between the two latching grooves 1444 and a receiving groove 1450 is defined throughout the arc-shaped element 1448.

The first flexible sidewall 14 and the second flexible sidewall 16 each define a number of hollows 15 to improve the tension and uniformity of the first flexible sidewall 14 and the second flexible sidewall 16.

Two bolts 17 are disposed on each inner surface of the first flexible sidewall 14 and the second flexible sidewall 16, and configured for being received in the inserting hole 201 of the hard disk 200 to position the hard disk 200 in the receiving cavity 101. It is noteworthy that the bolts 17 are integrated with the first flexible sidewall 14 and the second flexible sidewall 16 correspondingly in this disclosure. In alternative disclosures, the bolts 17 can be inserted into the inserting hole 201 through holes (not shown) predefined on the first flexible sidewall 14 and the second flexible sidewall 16. Furthermore, the third borders 144 of the first flexible sidewall 14 and the second flexible sidewall 16 each include an extended flange 146. The flanges 146 extend towards each other and parallel to the bottom 12, for limiting the vertical movement of the hard disk 200 in the hard disk bracket assembly 100.

The locking portion 20 includes a first edge 22 and a second edge 24 opposite to the first edge 22. The first edge 22 rotatably connects to the first flexible sidewall 14. The second edge 24 is secured to the second sidewall 16 by the screws 1446. In the present disclosure, the locking portion 20 is substantially “X” shaped.

In detail, the first edge 22 includes two hinges 220 for being pivotably received in the pivoting hole 1442 of the first flexible sidewall 14, so that the locking portion 20 is rotatable about the first flexible sidewall 14. The second edge 24 protrudes two latching portions 240 for latching with the corresponding latching grooves 1444 of the second flexible sidewall 16. Each latching portion 240 defines a second screw hole 242 corresponding to the first screw hole 160. The latching portions 240 can be fixed to the second flexible sidewall 16 by the screws 1446 received in the first screw hole 160 and the second screw hole 242.

The locking portion 20 further includes an elastic element 26 disposed between the latching portions 240. The elastic element 26 includes a ring-shaped portion 260 and a connecting portion 262 connecting the ring-shaped portion 260 to one of the latching portions 240. The ring-shaped portion 260 is configured for assisting in opening of the locking portion 20 relative to the holding portion 10, while the connecting portion 262 is configured for buffering the locking portion 20. The ring-shaped portion 260 further includes a latching block 264 configured for being received in the receiving groove 1450, thereby locking the locking portion 20 to the holding portion 10.

When in assembly, the first flexible sidewall 14 and the second flexible sidewall 16 are pulled away from each other by users. The hard disk 200 is positioned in the receiving cavity 101 and the bolts 17 are received in the inserting holes 201 respectively. The latching portions 240 are received in the latching grooves 1444. The screws 1446 are screwed into the latching grooves 1444 through the first screw holes 160 correspondingly until the hard disk bracket assembly 100 applies pressure on the hard disk 200. The latching block 264 is latched to the receiving groove 1450, so that the locking portion 20 locks the hard disk 200 in the hard disk bracket assembly 100. When removing the hard disk 200 from the hard disk bracket assembly 100, it is needed to just take out the screws 1446 and slightly pull the first flexible sidewall 14 and the second flexible sidewall 16 away from each other, and the hard disk 200 can be easily removed.

When in use, the hard disk 200 produces vibration due to the rotation of the magnetic head. The pressure applied on the hard disk 200 counteracts the vibration, thereby reducing the vibration. Therefore, the hard disk 200 has a good performance with reduced vibration.

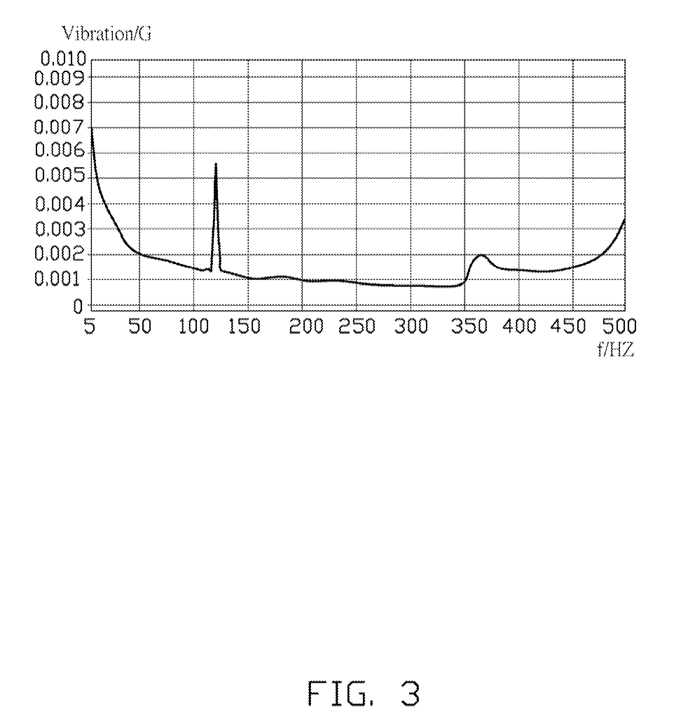

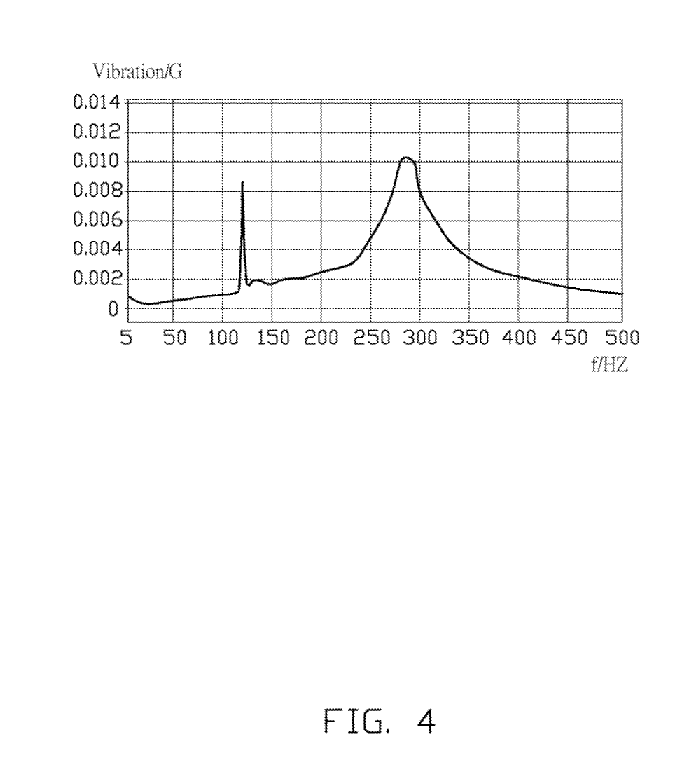

Referring to FIGS. 3 and 4, FIG. 3 shows a schematic graph showing the vibration test result of a hard disk fixed by the hard disk bracket assembly 100, and FIG. 4 shows a schematic graph showing the vibration test result of the hard disk not fixed by the hard disk bracket assembly. In the present disclosure, the horizontal axis represents working frequency f (Hz) of the hard disk 200, and the vertical axis represents vibration of the hard disk 200. It is obvious, that in a band of 150400 Hz working frequency, the vibration of the hard disk 200 is significantly reduced when being fixed by the hard disk bracket assembly 100 as compared to not being fixed by the hard disk bracket assembly.

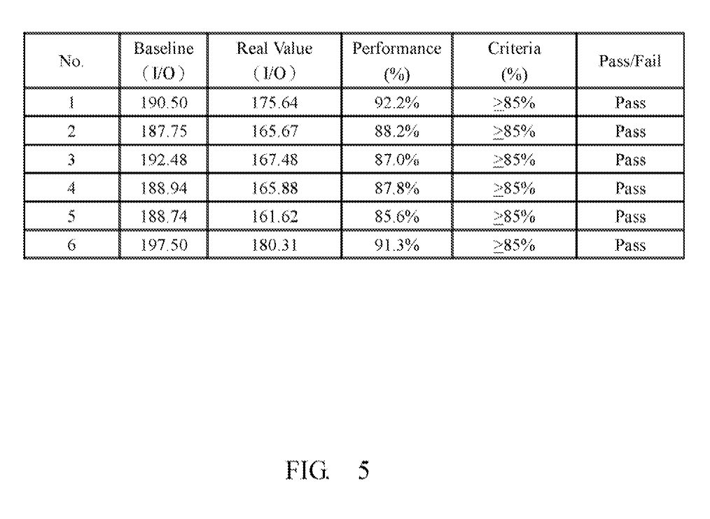

Also referring to FIG. 5, a data sheet showing the test results of the hard disk bracket assembly 100 is shown. The data sheet shows that the performance of the hard disk 200 satisfies the requirements of the user after the bracket assembly 100 fixes the hard disk 200.

While various exemplary and preferred embodiments have been described, it is to be understood that the disclosure is not limited thereto. To the contrary, various modifications and similar arrangements (as would be apparent to those skilled in the art), are also covered. Therefore, the scope of the appended claims should be accorded the broadest interpretation so as to encompass all such modifications and similar arrangements.

What is claimed is:

1. A hard disk bracket assembly for fixing a hard disk, comprising:
a holding portion comprising a bottom wall, a first flexible sidewall and a second flexible sidewall, the first flexible sidewall and the second flexible sidewall substantially perpendicular to the bottom wall, the bottom wall interconnecting the first flexible sidewall and the second flexible sidewall; and
a locking portion cooperatively defining a receiving cavity with the holding portion for receiving the hard disk, the locking portion comprising a first edge and a second edge opposite to the first edge, the first edge hinged to the first flexible sidewall while the second edge being configured for being engaged with the second flexible sidewall, to lock the hark disk in the receiving cavity.

2. The hard disk bracket assembly of claim 1, wherein the hard disk defines a plurality of inserting holes on opposite sidewalls thereof, a plurality of bolts are disposed on the inner surfaces of the first flexible sidewall and the second flexible sidewall corresponding to the inserting holes, the bolts are configured for positioning the hard disk in the receiving cavity when the bolts being received in the inserting holes.

3. The hard disk bracket assembly of claim 1, wherein the hard disk bracket assembly is made of polymethyl methacrylate (PMMA) or polycarbonate (PC).

4. The hard disk bracket assembly of claim 1, wherein the bottom wall comprises a limiting portion extending upwards and having a height lower than the first flexible sidewall and the second flexible sidewall.

5. The hard disk bracket assembly of claim 1, wherein the first flexible sidewall and the second flexible sidewall each include a first border away from the limiting portion, a second border adjacent to the limiting portion, and a third border interconnecting the first border and the second border, the extending directions of the first border and the second border are substantially perpendicular to the bottom wall while that of the third border is parallel to the bottom wall.

6. The hard disk bracket assembly of claim 5, wherein the first borders each have a resisting portion protruding and running parallel to the limiting portion, and the resisting portions extend towards each other, the resisting portions are configured for resisting a main box of a computer.

7. The hard disk bracket assembly of claim 5, wherein the first and second flexible sidewalls each extend a flexible arm along a direction away from the second border, wherein the flexible arm comprises a bending portion and an operating portion integrated with the bending portion, when a user presses the operating portion, the bending portion flexibly deforms to resist the hard disk.

8. The hard disk bracket assembly of claim 7, wherein a first protrusion is formed between the bending portion and the operating portion, the first protrusion extends towards the receiving cavity and configured for applying pressure to the hard disk when the hard disk is received in the hard disk bracket assembly.

9. The hard disk bracket assembly of claim 5, wherein the third border of the second flexible sidewall defines two latching grooves extending to the bottom wall therefrom, the second flexible sidewall defines two first screw holes thereon, the latching grooves perpendicularly communicate with the first screw hole, the second border of the locking portion comprises two latching portions for latching with the latching grooves, each latching portion defines a second screw hole corresponding to the first screw hole, the latching portions is configured for being fixed on the second flexible sidewall by a screw received in the first screw hole and the second screw hole.

10. The hard disk bracket assembly of claim 9, wherein the length of the screw along the axis thereof is larger than that of the first screw hole.

11. The hard disk bracket assembly of claim 9, wherein an elastic element is disposed between the two latching portions, the elastic element comprises a ring-shaped portion and a connecting portion connecting the ring-shaped portion to the latching portion, the ring-shaped portion is configured for assisting in opening the locking portion relative to the holding portion, while the connecting portion is configured for buffering the locking portion.

12. The hard disk bracket assembly of claim 11, wherein the third border of the second flexible sidewall comprises an arc-shaped element disposed between the two latching grooves, the arc-shaped element defines a receiving groove therein, the ring-shaped portion further comprises a block configured for being received in the receiving groove.

13. The hard disk bracket assembly of claim 1, wherein the locking portion is substantially “X” shaped.
